(19) United States
(12) Patent Application Publication
(10) Pub. No.: US 2026/0233265 A1
(43) Pub. Date: Aug. 13, 2026

(54) SUBSTRATE CLEANING SYSTEM

(71) Applicant: KCTECH CO., LTD., Gyeonggi-do (KR)

(72) Inventors: GEUN SIK YUN, Gyeonggi-do (KR); TAE HYUNG KIM, Gyeonggi-do (KR)

(73) Assignee: KCTECH CO., LTD., Gyeonggi-do (KR)

(21) Appl. No.: 19/457,161

(22) Filed: Jan. 23, 2026

(30) Foreign Application Priority Data
Feb. 10, 2025 (KR) 10-2025-0016603

(51) Int. Cl. B08B 13/00; B08B 1/12; B08B 1/34

(52) U.S. Cl. CPC B08B 13/00; B08B 1/12; B08B 1/34

(57) ABSTRACT

The substrate cleaning system includes a support device and a cleaning device including a pair of brushes configured to clean a surface of the substrate supported by the support device, wherein the support device may include a first drive holder configured to support the edge of the substrate, rotate about a first central axis, and rotate the substrate, a second drive holder configured to support the edge of the substrate, rotate about a second central axis, and rotate the substrate, and a support module configured to support the edge of the substrate, freely rotate in conjunction with rotation of the substrate by the first drive holder and the second drive holder, and configured such that a height relative to the ground is adjustable, wherein the first drive holder, the second drive holder, and the support module may be configured to support different points on the edge of the substrate.

### CROSS-REFERENCE TO RELATED APPLICATIONS

This application claims the benefit of Korean Patent Application No. 10-2025-0016603, filed on Feb. 10, 2025, in the Korean Intellectual Property Office, the entire disclosure of which is incorporated herein by reference for all purposes.

### BACKGROUND

### Field of the Invention

One or more embodiments relate to a substrate cleaning system.

### Description of the Related Art

Typically, a semiconductor is manufactured through a series of repetitive processes, such as lithography, deposition, and etching. These repetitive processes leave behind contaminants such as various particles, metallic impurities, and organic substances on a surface of a substrate included in such a semiconductor. Since these contaminants degrade reliability of the manufactured semiconductor, to improve this, a cleaning or buffing process is required during the semiconductor manufacturing process. The substrate cleaning process may be performed using a brush, but pressure exerted by the brush may deform the surface of the substrate. Accordingly, research and development is underway on technology of maintaining the center between the surface of the substrate and the brush.

However, the foregoing should not be construed as having been acknowledged by the applicant as a prior art to the description set forth in the disclosure, but should be construed only as a related art to the disclosure described herein.

### SUMMARY

Embodiments provide a substrate cleaning system for automatically aligning the center between a substrate and a brush.

Embodiments provide a substrate cleaning system for minimizing substrate warpage and thus increasing substrate process efficiency.

The technical goals to be achieved by the substrate cleaning system are not limited to those described above, and other goals not mentioned above can be clearly understood by one of ordinary skill in the art from the following description.

According to an aspect, there is provided a substrate cleaning system including a support device configured to support an edge of a substrate and a cleaning device including a pair of brushes configured to clean a surface of the substrate supported by the support device, wherein the support device may include a first drive holder configured to support the edge of the substrate, rotate about a first central axis, and rotate the substrate, a second drive holder configured to support the edge of the substrate, rotate about a second central axis, and rotate the substrate, and a support module configured to support the edge of the substrate, freely rotate in conjunction with rotation of the substrate by the first drive holder and the second drive holder, and configured such that a height relative to the ground is adjustable, wherein the first drive holder, the second drive holder, and the support module may be configured to support different points on the edge of the substrate.

Based on a state in which the support device supports the substrate, the first drive holder, the second drive holder, and the support module may be placed to form an angle of 120 degrees with respect to a center of the substrate.

When viewed from an upper portion of the substrate, the pair of brushes may be placed in a direction parallel to a virtual connection line connecting the first central axis to the second central axis.

Each of the brushes may rotate about a central axis parallel to a longitudinal direction, and when viewed in a cross-section perpendicular to the longitudinal direction, rotation directions of the pair of brushes may be opposite to each other.

The support module may include a rotation plate, an actuator configured to bidirectionally rotate the rotation plate about a rotation axis, and an idle holder placed on an upper portion of the rotation plate and rotatably connected about a central axis parallel to the rotation axis.

The support module may further include a connection member configured to connect the idle holder to the rotation plate so as to be movable relative to each other, and the connection member may be connected to the rotation plate so as to be inserted into or withdrawn from the rotation plate.

The idle holder may include a first support surface that is formed to be inclined with respect to the central axis of the idle holder and on which the edge of the substrate is placed.

Each of the first drive holder and the second drive holder may include a rotation frame that rotates by receiving power from an actuator and a rotation head connected to an upper portion of the rotation frame and configured to engage with the edge of the substrate.

The rotation head may further include a second support surface formed to be inclined with respect to a central axis of the rotation head and on which the edge of the substrate is placed.

Additional aspects of embodiments will be set forth in part in the description which follows and, in part, will be apparent from the description, or may be learned by practice of the disclosure.

According to embodiments, a substrate cleaning system may maintain uniform cleaning power and may improve cleaning quality by precisely adjusting a position between a brush and a substrate through a function of automatically aligning the center between the brush and the substrate.

According to embodiments, a substrate cleaning system may simplify design and may increase efficiency of a cleaning process by utilizing a three-point support structure and a precision control system.

The effects of the substrate cleaning system according to embodiments are not limited to the above-mentioned effects, and other unmentioned effects can be clearly understood from the following description by one of ordinary skill in the art.

### BRIEF DESCRIPTION OF THE DRAWINGS

The accompanying drawings illustrate preferred embodiments of the present disclosure and are provided together with the detailed description for better understanding of the technical idea of the present disclosure. Therefore, the present disclosure should not be construed as being limited to the embodiments set forth in the drawings.

These and/or other aspects, features, and advantages of the disclosure will become apparent and more readily appreciated from the following description of embodiments, taken in conjunction with the accompanying drawings of which:

FIG. 1 is a perspective view of a substrate cleaning system according to an embodiment;

FIG. 2 is a diagram illustrating positions of a first drive holder, a second drive holder, a support module, and a brush, according to an embodiment;

FIG. 3 is a diagram illustrating a mechanism of adjusting a rotation direction of a brush and a height of a support module, according to an embodiment; and

FIG. 4 is a diagram illustrating how flatness of a substrate is maintained by adjusting a height of a support module, according to an embodiment.

### DETAILED DESCRIPTION

Hereinafter, embodiments will be described in detail with reference to the accompanying drawings. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms "a", "an", and "the" are intended to include the plural forms as well, unless the context clearly indicates otherwise. It will be further understood that the terms "comprises/comprising" and/or "includes/including" when used herein, specify the presence of stated features, integers, steps, operations, elements, and/or components, but do not preclude the presence or addition of one or more other features, integers, steps, operations, elements, components and/or groups thereof.

Unless otherwise defined, all terms, including technical and scientific terms, used herein have the same meaning as commonly understood by one of ordinary skill in the art to which the present disclosure pertains. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components regardless of drawing numbers and a repeated description related thereto will be omitted. In the description of embodiments, detailed description of well-known related structures or functions will be omitted when it is deemed that such description will cause ambiguous interpretation of the present disclosure. It is to be understood that a singular form of a noun corresponding to an item may include one or more of the things, unless the relevant context clearly indicates otherwise. As used herein, "A or B", "at least one of A and B", "at least one of A or B", "A, B or C", "at least one of A, B and C", and "at least one of A, B, or C," each of which may include any one of the items listed together in the corresponding one of the phrases, or all possible combinations thereof.

Also, in the description of the components of the embodiments, terms such as first, second, A, B, (a), (b), and the like may be used. These terms are used only for the purpose of discriminating one component from another component, and the nature, the sequences, or the orders of the components are not limited by the terms. When one component is described as being "connected", "coupled", or "attached" to another component, it should be understood that one component may be connected or attached directly to the other component, and an intervening component may also be "connected", "coupled", or "attached" to the components.

As used herein, the terms "substantially", "approximately", "generally", and "about" in reference to a given parameter, property, or condition may include a degree that one of ordinary skill in the art would understand that the given parameter, property, or condition is met with a small degree of variance, such as within acceptable manufacturing tolerances. For example, a parameter that is substantially met may be at least 90% met, at least 95% met, or at least 99% met.

Components included in an embodiment and components having a common function will be described using the same names in other embodiments. Unless otherwise mentioned, the descriptions of an embodiment may be applicable to other embodiments and thus, repeated descriptions will be omitted for conciseness.

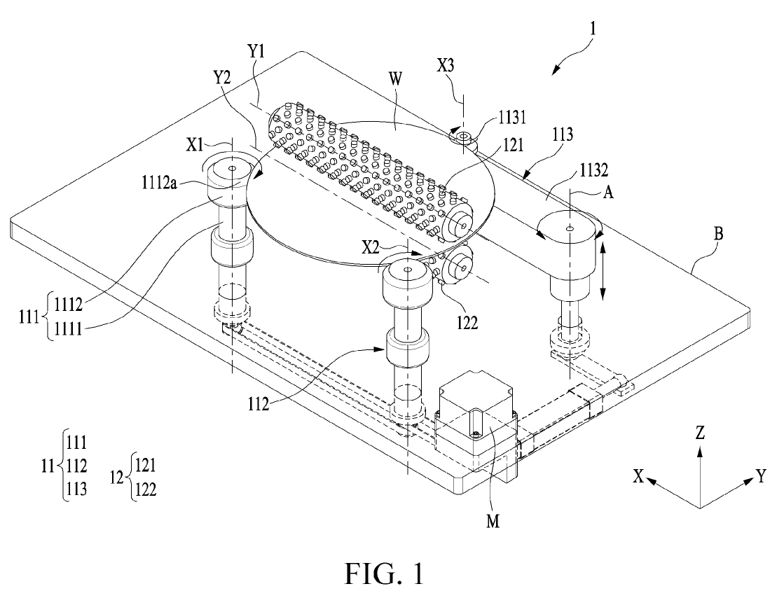

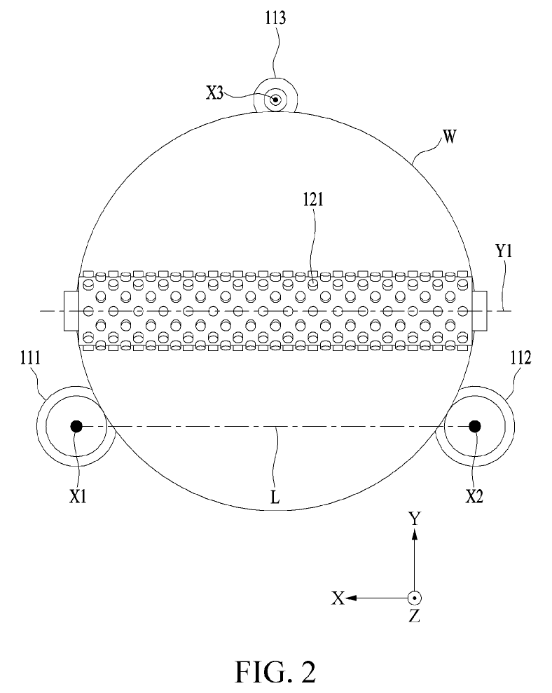

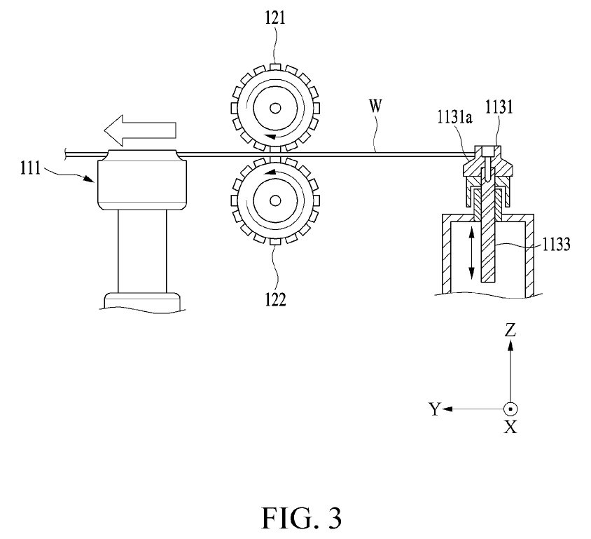

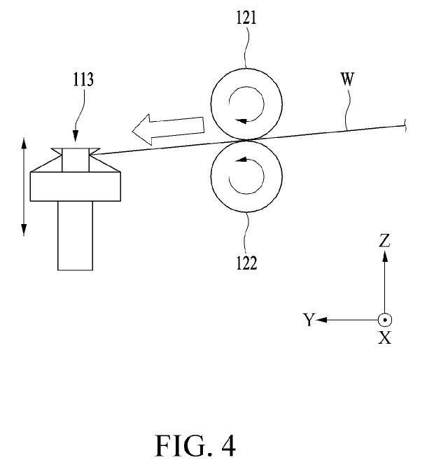

FIG. 1 is a perspective view of a substrate cleaning system according to an embodiment. FIG. 2 is a diagram illustrating positions of a first drive holder, a second drive holder, a support module, and a brush, according to an embodiment. FIG. 3 is a diagram illustrating a mechanism of adjusting the rotation direction of a brush and the height of a support module, according to an embodiment. FIG. 4 is a diagram illustrating how flatness of a substrate is maintained by adjusting the height of a support module, according to an embodiment. In the following description of the substrate cleaning system, with respect to directions shown in the drawings, "an upper portion" may refer to a +Z-axis direction, and "a lower portion" may refer to a -Z-axis direction. For example, "an upper surface" may refer to a surface facing the +Z-axis direction, and "a lower surface" may refer to a surface facing the -Z-axis direction.

Referring to FIGS. 1 to 4, a substrate cleaning system 1 according to an embodiment may clean a substrate W. For example, the substrate cleaning system 1 may clean the substrate W that is cleaned, buffed, or polished, particularly a surface of the substrate W. The substrate cleaning system 1 may support the substrate W through a support device 11. The substrate cleaning system 1 may clean the substrate W supported by the support device 11 through a cleaning device 12. In an embodiment, the substrate cleaning system 1 may include a base B, the support device 11, and the cleaning device 12.

In an embodiment, the base B may form a lower portion of the substrate cleaning system 1. For example, the base B may be placed on the ground to support other components (e.g., the support device 11 and/or the cleaning device 12) of the substrate cleaning system 1.

In an embodiment, the support device 11 may support the substrate W. The support device 11 may be placed on the base B. The support device 11 may support the edge of the substrate W. The support device 11 may rotate the supported substrate W. The substrate W supported and rotated by the support device 11 may have the surface cleaned using the cleaning device 12 described below.

In an embodiment, the support device 11 may support different points of the substrate W. For example, the support device 11 may support the substrate W in a three-point support configuration at three different points. The support device 11 may include a first drive holder 111, a second drive holder 112, and a support module 113 that support different points of the edge of the substrate W. In an embodiment, based on a state in which the support device 11 supports the substrate W (e.g., the state shown in FIG. 1), the first drive holder 111, the second drive holder 112, and the support module 113 may be placed to form an angle of 120 degrees with respect to the center of the substrate W. By supporting different points on the edge of the substrate W, the support device 11 may more stably support the substrate W during a process of cleaning the substrate W.

In an embodiment, the first drive holder 111 and the second drive holder 112 may each support different points on the substrate W and may rotate the supported substrate W. For example, the first drive holder 111 and the second drive holder 112 may be connected to an actuator M to receive power. The first drive holder 111 may rotate about a first central axis X1 and may rotate the substrate W. The second drive holder 112 may rotate about a second central axis X2 and may rotate the substrate W. The first central axis X1 of the first drive holder 111 and the second central axis X2 of the second drive holder 112 may be parallel to each other in a direction perpendicular to the ground (e.g., a Z-axis direction). The rotation direction of the first drive holder 111 and the rotation direction of the second drive holder 112 may be the same. The rotation direction of the first drive holder 111 and the second drive holder 112 is illustrated as being clockwise but is not limited thereto, and the first drive holder 111 and the second drive holder 112 may also rotate counterclockwise.

In an embodiment, each of the first drive holder 111 and the second drive holder 112 may include a rotation frame (e.g., a first rotation frame 1111), which receives power from a motor to rotate, and a rotation head (e.g., a first rotation head 1112) that is connected to an upper portion of the rotation frame and engages with the edge of the substrate W. Since the second drive holder 112 may be provided with substantially the same structure as the first drive holder 111, the following description focuses on the structure of the first drive holder 111. It should be noted that the description of the structure of the first drive holder 111 described below may also be equally applied to the second drive holder 112 unless otherwise stated.

In an embodiment, the first drive holder 111 may include the first rotation frame 1111 and the first rotation head 1112. The first rotation frame 1111 may be connected to the actuator M to receive power. The first rotation frame 1111 that has received the power may rotate around the first central axis X1. In an embodiment, rotation speeds of the first drive holder 111 and the second drive holder 112 with respect to the first central axis X1 and the second central axis X2, respectively, may be substantially the same. The rotation speeds of the first drive holder 111 and the second drive holder 112 may determine the rotation speed of the substrate W, and the rotation speeds of the first drive holder 111 and the second drive holder 112 may be controlled by a controller (not shown) according to a cleaning degree of the surface of the substrate W.

In an embodiment, the first rotation head 1112 may be connected to an upper portion of the first rotation frame 1111. The first rotation head 1112 may rotate around the first central axis X1 together with the first rotation frame 1111 as the first rotation frame 1111 rotates around the first central axis X1. The edge of the substrate W may be engaged with the first rotation head 1112. For example, a second support surface 1112a may be formed on the first rotation head 1112. The second support surface 1112a may be formed to be inclined with respect to a central axis of the first rotation head 1112 (e.g., the central axis of the first rotation head 1112 parallel to the first central axis X1) so that the edge of the substrate W is positioned on the second support surface 1112a. In another embodiment, the second support surface 1112a may be formed as a curved surface that is concave toward the central axis while facing downward (e.g., the -Z-axis direction of FIG. 1) from an upper end of the first rotation head 1112. The second support surfaces 1112a formed on the first rotation head 1112 and a second rotation head may ensure stable support and rotational drive by more stably engaging with the edge of the substrate W with the rotation heads.

In an embodiment, the support module 113 may be placed at a distance apart from the first drive holder 111 and the second drive holder 112 to support the edge of the substrate W. As the substrate W is rotated by the first drive holder 111 and the second drive holder 112, the support module 113 may freely rotate around a third central axis X3. For example, the support module 113 may freely rotate in conjunction with the rotation of the substrate W by the first drive holder 111 and the second drive holder 112. The support module 113 may support the edge of the substrate W while rotating in an idle manner without interfering with the rotation of the substrate W. In an embodiment, the support module 113 may be provided so that the height relative to the ground is adjustable. The support module 113 may include an idle holder 1131 that engages with the edge of the substrate W, a rotation plate 1132 that is connected to the idle holder 1131 and rotates the idle holder 1131, and a connection member 1133 that connects the idle holder 1131 to the rotation plate 1132.

In an embodiment, the idle holder 1131 may be placed on an upper portion of the rotation plate 1132. The idle holder 1131 may perform driven rotation around the third central axis X3 of the idle holder 1131 as the substrate W is rotated by the first driving holder 111 and the second driving holder 112. The edge of the substrate W may be engaged with the idle holder 1131. For example, the idle holder 1131 may be formed with a first support surface 1131a. The first support surface 1131a may be formed to be inclined with respect to the third central axis X3 of the idle holder 1131 so that the edge of the substrate W is positioned thereon. In another embodiment, the first support surface 1131a of the idle holder 1131 may be formed in a curved shape that is concave toward the third central axis X3 while facing downward from an upper end of the idle holder 1131.

In an embodiment, the rotation plate 1132 may rotate the idle holder 1131 about a rotation axis A. For example, the rotation plate 1132 may be connected to an actuator (not shown) to receive power and may be rotated about the rotation axis A by the received power. With respect to the substrate W supported by the first drive holder 111 and the second drive holder 112, the rotation plate 1132 may rotate counterclockwise about the rotation axis A to make the edge of the substrate W contact with the idle holder 1131. After the cleaning of the substrate W is completed, the rotation plate 1132 may rotate clockwise about the rotation axis A to separate the substrate W from the idle holder 1131. As described above, the rotation plate 1132 may be provided to rotate around the rotation axis A so that the idle holder 1131 may contact with or be separated from the edge of the substrate W, thereby increasing convenience of mounting or detaching the substrate W from the substrate cleaning system 1.

In an embodiment, the connection member 1133 may connect the idle holder 1131 to the rotation plate 1132. For example, the connection member 1133 may connect the idle holder 1131 to the rotation plate 1132 so as to be relatively movable with respect to each other. For example, the connection member 1133 may be connected to the inside of the rotation plate 1132 so as to be inserted into or withdrawn from the rotation plate 1132. The connection member 1133 may adjust the height of the idle holder 1131 connected to the upper portion of the rotation plate 1132 by moving so as to be inserted into or withdrawn from the rotation plate 1132. Adjusting the height of the idle holder 1131 by the connection member 1133 may maintain the surface of the substrate W to be cleaned in the substrate cleaning system 1 flat. A detailed description thereof is provided below in the paragraph describing the cleaning device 12.

In an embodiment, the cleaning device 12 may be placed to contact the surface of the substrate W to clean the surface of the substrate W. The cleaning device 12 may include a pair of brushes (e.g., an upper brush 121 and a lower brush 122) for cleaning the surface of the substrate W. Referring to FIG. 2, the pair of brushes (e.g., the upper brush 121 and the lower brush 122) according to an embodiment may be placed in a direction parallel to a virtual connection line L connecting the first central axis X1 of the first drive holder 111 and the second central axis X2 of the second drive holder 112. For example, an axis Y1 that is parallel to the longitudinal direction of any one (e.g., the upper brush 121) of the pair of brushes (e.g., the upper brush 121 and the lower brush 122) may be parallel to the connection line L. Through such a placement relationship, the pair of brushes (e.g., the upper brush 121 and the lower brush 122) may be placed without causing interference with a drive holder and the support module 113, thereby evenly cleaning the surface of the substrate W. In an embodiment, the pair of brushes (e.g., the upper brush 121 and the lower brush 122) may include the upper brush 121 for cleaning the upper surface of the substrate W and the lower brush 122 for cleaning the lower surface of the substrate W.

In an embodiment, the upper brush 121 and the lower brush 122 may be rotationally driven about central axes (e.g., the axis Y1 and an axis Y2) parallel to respective longitudinal directions (e.g., an X-axis direction). Although not shown in the drawing, the upper brush 121 and the lower brush 122 may each be connected to the separate actuator M (e.g., a motor) that transmits power. Rotation speeds of the upper brush 121 and the lower brush 122 may be substantially the same but may differ from each other depending on various factors, such as a cleaning state of the substrate W. In an embodiment, a rotational force applied by the upper brush 121 to the upper surface of the substrate W and a rotational force applied by the lower brush 122 to the lower surface of the substrate W may be the same or may be different depending on various factors. When the rotational forces applied by the upper brush 121 and the lower brush 122 are different, the surface of the substrate W may be formed to be concave (e.g., when the surface of the substrate W of FIG. 3 is bent in the -Z-axis direction) or convex (e.g., when the surface of the substrate W of FIG. 3 is bent in the +Z-axis direction). Here, the connection member 1133 of the support module 113 may be raised (e.g., raised in the +Z-axis direction of FIG. 3) or lowered (e.g., lowered in the -Z-axis direction of FIG. 3) to maintain the surface of the substrate W flat. By maintaining the surface of the substrate W flat, self-centering may be achieved so that the substrate W is aligned with the center between the upper brush 121 and the lower brush 122, thereby preventing or reducing a decrease in cleaning efficiency.

In an embodiment, when viewed in a cross-section (e.g., a YZ plane of FIG. 3) that is perpendicular to the longitudinal direction, the rotation directions of the upper brush 121 and the lower brush 122 may be opposite to each other. In addition, with respect to the substrate W receiving the rotational force of the cleaning device 12, the rotation directions of the upper brush 121 and the lower brush 122 may be the same. For example, as shown in FIG. 3, the upper brush 121 may apply the rotational force in the leftward direction (e.g., a −Y-axis direction of FIG. 3) to the upper surface of the substrate W, and the lower brush 122 may apply the rotational force in the leftward direction to the lower surface of the substrate W. In this method, by applying the rotational force in the same direction to the surface of the substrate W by the upper brush 121 and the lower brush 122, the substrate W may be pushed in one direction, and the edge of the substrate W pushed by the rotational force may be more easily engaged with rotation heads of the first driving holder 111 and/or the second drive holder 112.

Although the embodiments have been described with reference to the limited number of drawings, it will be apparent to one of ordinary skill in the art that various modifications and variations may be made to the embodiments. For example, suitable results may be achieved if the described techniques are performed in a different order, and/or if components in a described system, architecture, device, or circuit are combined in a different manner, or replaced or supplemented by other components or their equivalents.

Therefore, other implementations, other embodiments, and/or equivalents of the claims are within the scope of the following claims.

What is claimed is:

1. A substrate cleaning system comprising:
a support device configured to support an edge of a substrate; and
a cleaning device comprising a pair of brushes configured to clean a surface of the substrate supported by the support device,
wherein the support device comprises:
a first drive holder configured to support the edge of the substrate, rotate about a first central axis, and rotate the substrate;
a second drive holder configured to support the edge of the substrate, rotate about a second central axis, and rotate the substrate; and
a support module configured to support the edge of the substrate, freely rotate in conjunction with rotation of the substrate by the first drive holder and the second drive holder, and configured such that a height relative to the ground is adjustable,
wherein the first drive holder, the second drive holder, and the support module are configured to support different points on the edge of the substrate.

2. The substrate cleaning system of claim 1, wherein,
based on a state in which the support device supports the substrate,
the first drive holder, the second drive holder, and the support module are placed to form an angle of 120 degrees with respect to a center of the substrate.

3. The substrate cleaning system of claim 2, wherein,
when viewed from an upper portion of the substrate,
the pair of brushes is placed in a direction parallel to a virtual connection line connecting the first central axis to the second central axis.

4. The substrate cleaning system of claim 3, wherein
each of the brushes rotates about a central axis parallel to a longitudinal direction, and
when viewed in a cross-section perpendicular to the longitudinal direction, rotation directions of the pair of brushes are opposite to each other.

5. The substrate cleaning system of claim 1, wherein
the support module comprises:
a rotation plate;
an actuator configured to bidirectionally rotate the rotation plate about a rotation axis; and
an idle holder placed on an upper portion of the rotation plate and rotatably connected about a central axis parallel to the rotation axis.

6. The substrate cleaning system of claim 5, wherein
the support module further comprises a connection member configured to connect the idle holder to the rotation plate so as to be movable relative to each other, and
the connection member is connected to the rotation plate so as to be inserted into or withdrawn from the rotation plate.

7. The substrate cleaning system of claim 6, wherein
the idle holder comprises a first support surface that is formed to be inclined with respect to the central axis of the idle holder and on which the edge of the substrate is placed.

8. The substrate cleaning system of claim 1, wherein
each of the first drive holder and the second drive holder comprises:
a rotation frame that rotates by receiving power from an actuator; and
a rotation head connected to an upper portion of the rotation frame and configured to engage with the edge of the substrate.

9. The substrate cleaning system of claim 8, wherein
the rotation head further comprises a second support surface formed to be inclined with respect to a central axis of the rotation head and on which the edge of the substrate is placed.
